(19) United States
(12) Patent Application Publication
(10) Pub. No.: US 2013/0017683 A1
(43) Pub. Date: Jan. 17, 2013

(54) METHOD OF MANUFACTURING SILICON CARBIDE SUBSTRATE AND METHOD OF MANUFACTURING SILICON CARBIDE SEMICONDUCTOR DEVICE

(71) Applicants: Tsubasa HONKE, Itami-shi (JP); Shin HARADA, Osaka-shi (JP); Kyoko OKITA, Itami-shi (JP)

(72) Inventors: Tsubasa HONKE, Itami-shi (JP); Shin HARADA, Osaka-shi (JP); Kyoko OKITA, Itami-shi (JP)

(73) Assignee: Sumitomo Electric Industries, Ltd., Osaka-shi (JP)

(21) Appl. No.: 13/543,018

(22) Filed: Jul. 6, 2012

Related U.S. Application Data
(60) Provisional application No. 61/507,797, filed on Jul. 14, 2011.

(30) Foreign Application Priority Data
Jul. 14, 2011 (JP) 2011-155303

(51) Int. Cl. H01L 21/316; H01L 21/311

(52) U.S. Cl. 438/694; 438/767; 257/E21.271; 257/E21.25

(57) ABSTRACT

A silicon carbide substrate is prepared. By exposing the silicon carbide substrate to an atmosphere having a nitrogen dioxide concentration greater than or equal to 2 μg/m³, an oxide film is formed on the silicon carbide substrate.

### BACKGROUND OF THE INVENTION

1. Field of the Invention

The present invention relates to a method of manufacturing a silicon carbide substrate, and a method of manufacturing a silicon carbide semiconductor device.

2. Description of the Background Art

The site where a semiconductor substrate is manufactured and the site where a semiconductor device is manufactured using the semiconductor substrate often differ. The manufactured semiconductor substrates are temporarily stored, and then transported to the site where semiconductor devices are to be manufactured.

A method of storing a semiconductor substrate is disclosed in, for example, Japanese Patent Laying-Open No. 2009-182341. According to this method, a GaN substrate is stored under an atmosphere in which the oxygen concentration is less than or equal to 18% by volume and/or the vapor concentration is less than or equal to 25 g/m³. According to this publication, oxidation at the surface of the GaN substrate can be suppressed, allowing the manufacturing of a semiconductor device of favorable properties.

When a semiconductor substrate is transported to the site where a semiconductor device is to be manufactured, the surface of the semiconductor substrate will be subjected to some influence by the transportation. As a result, the property of the semiconductor device may be adversely affected. Specifically, the property of the semiconductor device may be degraded due to the contamination or mechanical damage at the surface of the semiconductor substrate during transportation. Such a negative effect may be particularly critical in the case where the semiconductor substrate is a silicon carbide substrate. For example, mechanical damage at the surface of a silicon carbide substrate may cause development of a stacked fault in an annealing step (for example, activation annealing) in manufacturing a semiconductor device using such a substrate. The presence of a stacking fault may degrade the reliability of the semiconductor device. Furthermore, in the case where epitaxial growth is carried out on the silicon carbide substrate, any contamination or mechanical damage at the surface may induce degradation in the crystallinity of the epitaxial layer.

### SUMMARY OF THE INVENTION

An object of the present invention is to provide a method of manufacturing a semiconductor device that can have influence on the property of the semiconductor device caused by transportation suppressed. Another object of the present invention is to provide a method of manufacturing a silicon carbide substrate that can have its surface protected from contamination or mechanical damage.

A method of manufacturing a silicon carbide substrate of the present invention includes the following steps. A silicon carbide substrate is prepared. An oxide film is formed on the silicon carbide substrate by exposing the silicon carbide substrate to an atmosphere having a nitrogen dioxide concentration greater than or equal to 2 μg/m³.

By exposing the silicon carbide substrate to an atmosphere having a nitrogen dioxide concentration greater than or equal to 2 μg/m³ according to the inventive method of manufacturing a silicon carbide substrate, an oxide film having a required thickness to protect the surface of the silicon carbide substrate can be formed with a thermal oxidation process being dispensable.

Preferably, the atmosphere has a nitrogen dioxide concentration greater than or equal to 5 μg/m³, more preferably greater than or equal to 10 μg/m³. Accordingly, an oxide film having sufficient thickness can be formed.

Preferably, the atmosphere has an oxygen concentration greater than or equal to 18% by volume. Accordingly, an oxide film can be formed more promptly.

Preferably, the atmosphere includes a vapor concentration greater than or equal to 25 g/m³. Accordingly, an oxide film can be formed more promptly.

During formation of an oxide film, the silicon carbide substrate is preferably exposed to the atmosphere for two hours or more. Accordingly, the thickness of the oxide film formed can be substantially saturated.

Preferably, the atmosphere has a nitrogen dioxide concentration less than or equal to 2 mg/m³. The workability can be improved since the atmosphere is absent of an excessively high nitrogen dioxide concentration.

A method of manufacturing a silicon carbide semiconductor device of the present invention includes the following steps. A silicon carbide substrate is prepared.

An oxide film is formed on the silicon carbide substrate by exposing the silicon carbide substrate to an atmosphere having a nitrogen dioxide concentration greater than or equal to 2 μg/m³. A silicon carbide substrate having an oxide film formed is transported. The oxide film is removed subsequent to transportation of the silicon carbide substrate.

According to a method of manufacturing a silicon carbide semiconductor device, the silicon carbide substrate has an oxide film formed thereon during transportation of the silicon carbide substrate. Accordingly, any effect during transportation mainly occurs on the oxide film. By removing the oxide film after transportation, any effect caused by transportation on the property of the silicon carbide semiconductor device can be suppressed.

The foregoing and other objects, features, aspects and advantages of the present invention will become more apparent from the detailed description of the present invention understood in conjunction with the accompanying drawings.

### BRIEF DESCRIPTION OF THE DRAWINGS

FIG. 1 is a sectional view schematically showing a configuration of a silicon carbide substrate according to a first embodiment of the present invention.

FIG. 2 is a sectional view schematically showing a method of using the silicon carbide substrate of FIG. 1.

FIG. 3 is a perspective view schematically showing a first step in a method of manufacturing a silicon carbide substrate according to a first embodiment of the present invention.

FIG. 4 is a sectional view schematically showing a configuration of a substrate storage cabinet identified as a manufacturing device employed in the method of manufacturing a silicon carbide substrate according to the first embodiment of the present invention.

FIGS. 5 and 6 are sectional views schematically showing second and third steps, respectively, of the method of manufacturing a silicon carbide substrate according to the first embodiment of the present invention.

FIG. 7 is a sectional view schematically showing a configuration of a silicon carbide substrate according to a second embodiment of the present invention.

FIG. 8 is a schematic sectional view of a method of using the silicon carbide substrate of FIG. 7.

FIG. 9 is a sectional view schematically showing a configuration of a silicon carbide semiconductor device according to a third embodiment of the present invention.

FIG. 10 is a flowchart schematically representing a method of manufacturing a silicon carbide semiconductor device according to the third embodiment of the present invention.

FIGS. 11-14 are schematic sectional views of the first to fourth steps, respectively, of the method of manufacturing a silicon carbide semiconductor device according to the third embodiment of the present invention.

FIG. 15 is a flowchart schematically showing a method of manufacturing a silicon carbide semiconductor device according to a fourth embodiment of the present invention.

### DESCRIPTION OF THE PREFERRED EMBODIMENTS

Embodiments of the present invention will be described hereinafter based on the drawings.

### First Embodiment

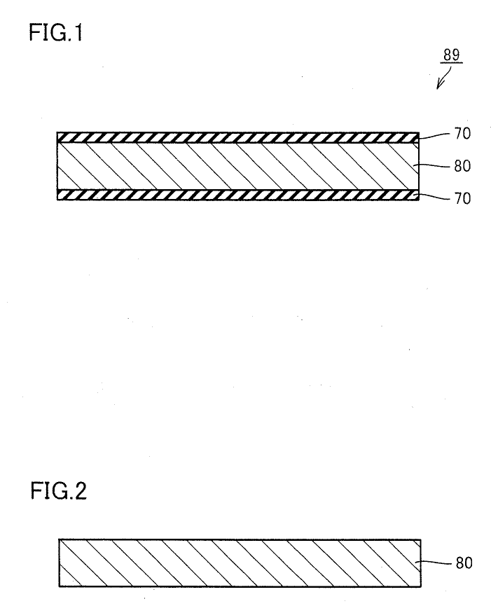

As shown in FIG. 1, a silicon carbide substrate 89 of the present embodiment includes a single crystal substrate 80 and an oxide film 70. Single crystal substrate 80 has a top face and back face. Oxide film 70 is formed on each of the top face and back face.

A method of using silicon carbide substrate 89 will be described hereinafter. Silicon carbide substrate 89 is transported under a state with oxide film 70 formed. This transportation starts from the site where silicon carbide substrate 89 is manufactured to the site where a semiconductor device is to be manufactured using silicon carbide substrate 89.

By removing oxide film 70 after transportation, at least one of the top face and back face of single crystal substrate 80 is exposed, as shown in FIG. 2. To this end, the so-called SPM (Sulfuric acid Peroxide Mixture) cleaning, for example, is carried out. In other words, cleaning based on a mixture solution of sulfuric acid and hydrogen peroxide is carried out. Then, by applying a semiconductor process to at least one of the top face and back face of single crystal substrate 80, a semiconductor device is manufactured.

A method of manufacturing silicon carbide substrate 89 will be described hereinafter.

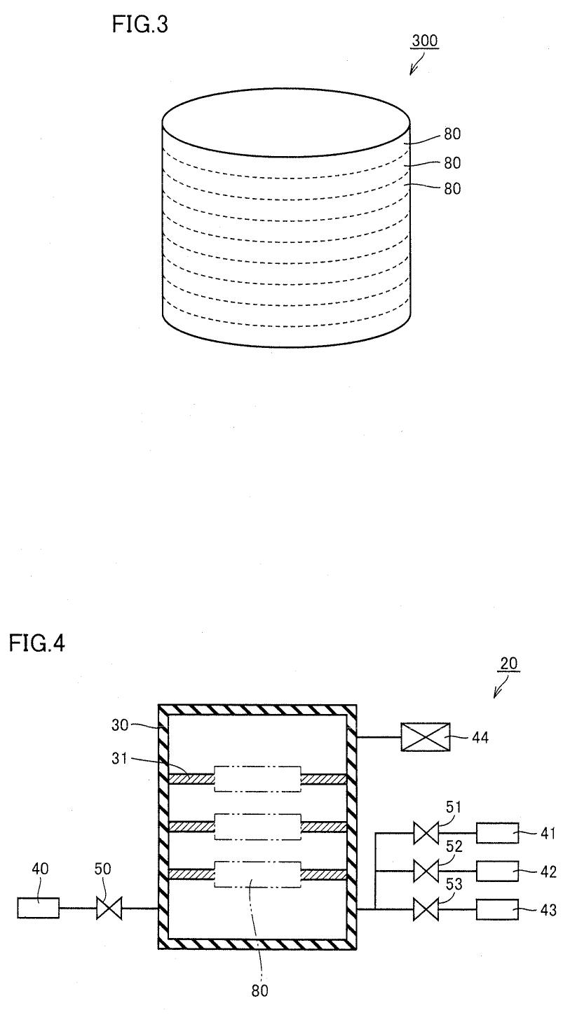

As shown in FIG. 3, silicon carbide single crystal 300 is prepared. Silicon carbide single crystal 300 can be formed by, for example, recrystallization through sublimation using seed crystal made of silicon carbide. Then, single crystal substrate 80 (silicon carbide substrate) is prepared using silicon carbide single crystal 300. Single crystal substrate 80 can be formed by slicing off from silicon carbide single crystal 300.

As shown in FIG. 4, a substrate storage cabinet 20 (silicon carbide substrate manufacturing device) is prepared. Substrate storage cabinet 20 includes a container 30, a fixture 31, an exhaust system 40, a nitrogen dioxide gas source 41, an oxygen gas source 42, a carrier gas source 43, a humidity adjuster 44, and valves 50-53. By this configuration, the atmosphere in container 30 can contain nitrogen dioxide and also at least oxygen or vapor. Furthermore, by providing a door at container 30, a substrate can be transferred into or out from container 30. Carrier gas source 43 is, for example, a nitrogen gas source. The carrier gas can be used to stably deliver the nitrogen dioxide gas. This carrier gas may be used as purge gas to reduce the nitrogen dioxide concentration in container 30 prior to discharge therefrom.

Fixture 31 serves to hold a substrate in container 30. Preferably, fixture 31 is configured to hold the side face of the substrate. In other words, fixture 31 is configured to hold a substrate without forming contact with the main surface of the substrate.

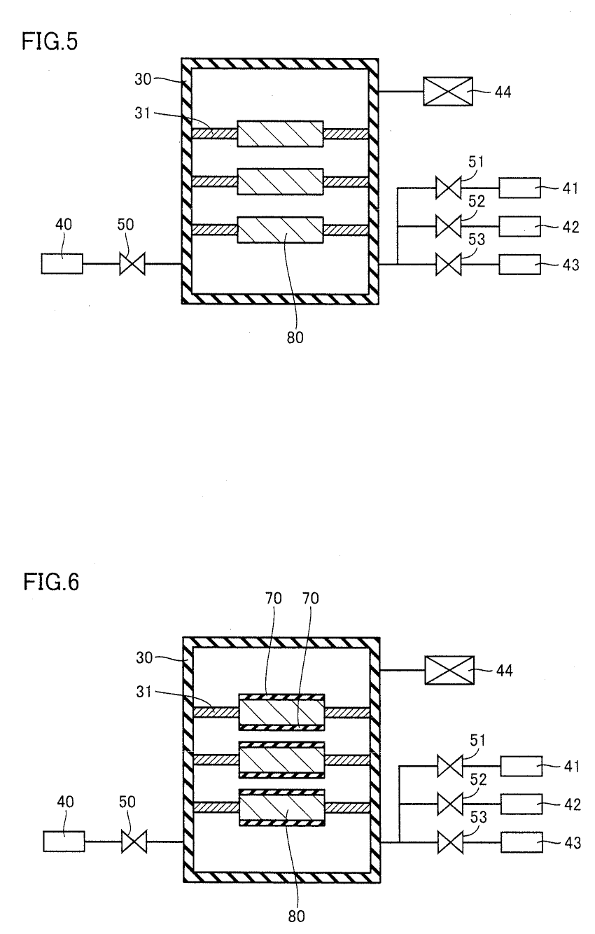

As shown in FIG. 5, single crystal substrate 80 is stored in container 30. It is assumed that the atmosphere in container 30 has a nitrogen dioxide concentration greater than or equal to 2 μg/m³. The nitrogen dioxide concentration is preferably greater than or equal to 5 μg/m³, more preferably greater than or equal to 10 μg/m³. Furthermore, the nitrogen dioxide concentration is preferably less than or equal to 2 mg/m³. Also preferably, the atmosphere has an oxygen concentration greater than or equal to 18% by volume. Also preferably, the atmosphere includes a vapor concentration greater than or equal to 25 g/m³. Further preferably, the atmosphere is at normal temperature. As a result of single crystal substrate 80 (silicon carbide substrate) being exposed to the above-described atmosphere, oxide film 70 is formed on single crystal substrate 80 (silicon carbide substrate), as shown in FIG. 6. Preferably, single crystal substrate 80 is exposed to the atmosphere for two or more hours.

Then, single crystal substrate 80 having oxide film 70 formed is taken out from container 30. Thus, silicon carbide substrate 89 (FIG. 1) is obtained.

By exposing single crystal substrate 80 to an atmosphere having a nitrogen dioxide concentration greater than or equal to 2 μg/m³ according to the present embodiment, oxide film 70 having a thickness required to protect the surface of single crystal substrate 80 can be formed. More specifically, an oxide film 70 having a thickness greater than or equal to 1 nm can be formed such that any damage that may be the cause of a stacking fault is less likely to occur at the surface of single crystal substrate 80. The atmosphere preferably has a nitrogen dioxide concentration greater than or equal to 5 μg/m³, more preferably greater than or equal to 10 μg/m³. Accordingly, oxide film 70 having sufficient thickness can be formed.

Formation of oxide film 70 can be carried out at normal temperature or at a temperature in the vicinity of normal temperature. Accordingly, an oxide film can be formed by a simpler step as compared to the case where formation of an oxide film is performed by thermal oxidization.

By using substrate storage cabinet 20 (FIG. 6), formation of oxide film 70 and storage of a substrate can be conducted concurrently. In other words, silicon carbide substrate 89 does not have to be transported to a substrate storage cabinet after formation of oxide film 70 (FIG. 1).

Preferably, the atmosphere has an oxygen concentration greater than or equal to 18% by volume. Accordingly, oxide film 70 can be formed more promptly.

Preferably, the atmosphere has a vapor concentration greater than or equal to 25 g/m³. Accordingly, oxide film 70 can be formed more promptly.

During formation of oxide film 70, single crystal substrate 80 is preferably exposed to the atmosphere for two or more hours. Accordingly, the thickness of oxide film 70 formed can be substantially saturated.

Preferably, the atmosphere has a nitrogen dioxide concentration less than or equal to 2 mg/m³. The workability can be improved since the atmosphere is absent of an excessively high nitrogen dioxide concentration. Specifically, even if container 30 is opened without replacing the atmosphere in container 30, the diffusion of nitrogen dioxide towards the environment is of a substantially negligible level.

Although nitrogen dioxide gas source 41 is provided outside container 30 at substrate storage cabinet 20 (FIG. 4) that is a manufacturing device of silicon carbide substrate 89 in the present embodiment, the supply source of nitrogen dioxide may be arranged in container 30. For example, nitric acid may be arranged in container 30 as the source of supplying nitrogen dioxide. In this case, the configuration of the manufacturing device of silicon carbide substrate 89 is rendered simpler.

### Second Embodiment

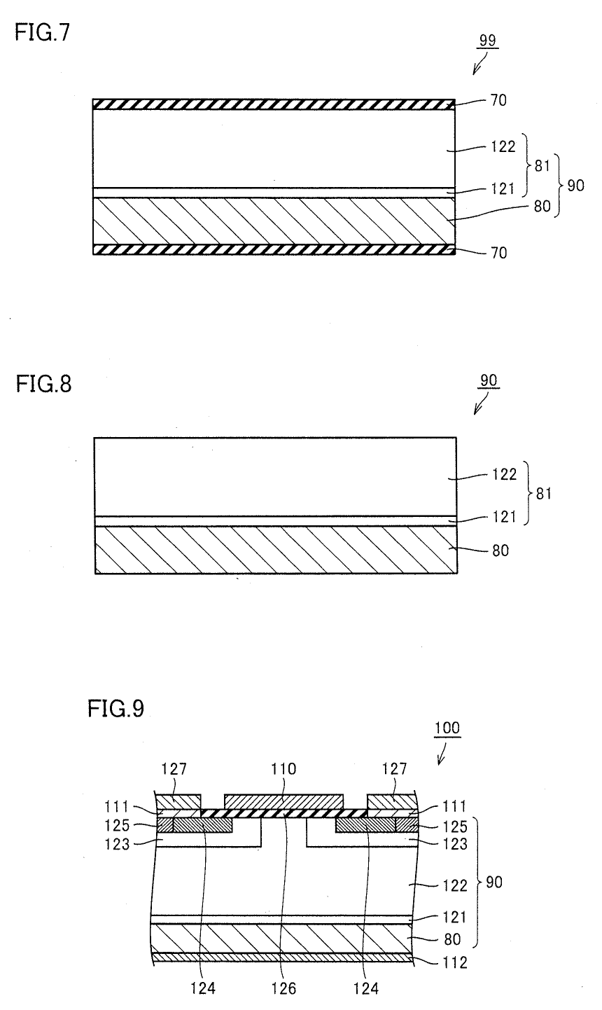

As shown in FIG. 7, a silicon carbide substrate 99 according to the present embodiment includes an epitaxial substrate 90 and oxide film 70. Oxide film 70 is formed on each of the top face and back face of the epitaxial substrate. Epitaxial substrate 90 includes a single crystal substrate 80 and an epitaxial layer 81. Epitaxial layer 81 includes a buffer layer 121 and a breakdown voltage holding layer 122.

A method of using silicon carbide substrate 99 will be described hereinafter. Silicon carbide substrate 99 is transported in a state with oxide film 70 formed. This transportation starts from the site where silicon carbide substrate 99 was manufactured up to the site where a semiconductor device is to be manufactured using silicon carbide substrate 99. By removing oxide film 70 subsequent to transportation, the surface of epitaxial layer 81 provided on epitaxial substrate 90 is exposed, as shown in FIG. 8. In other words, an epitaxial substrate 90 having oxide film 70 removed is obtained. Then, a semiconductor process is performed on epitaxial layer 81 of epitaxial substrate 90 to manufacture a semiconductor device.

A method of manufacturing silicon carbide substrate 99 will be described hereinafter. First, single crystal substrate 80 is formed by the method described in the first embodiment (FIG. 3). Then, by forming epitaxial layer 81 on single crystal substrate 80, epitaxial substrate 90 is obtained (FIG. 8). Then, by a method similar to the method of forming oxide film 70 on single crystal substrate 80 in the first embodiment (FIG. 6), oxide film 70 is formed on epitaxial substrate 90 (FIG. 7). Thus, silicon carbide substrate 99 is obtained.

According to the present embodiment, an advantage substantially similar to that of the first embodiment is obtained at silicon carbide substrate 99 with epitaxial layer 81, i.e. the epitaxial substrate.

### Third Embodiment

As shown in FIG. 9, a semiconductor device according to the present embodiment is a MOSFET 100, specifically a vertical type DiMOSFET (Double Implanted MOSFET). MOSFET 100 includes an epitaxial substrate 90, a gate insulating film 126, a source electrode 111, an upper source electrode 127, a gate electrode 110, and a drain electrode 112. Epitaxial substrate 90 includes a single crystal substrate 80, a buffer layer 121, a breakdown voltage holding layer 122, a p region 123, an n⁺ region 124 and a p⁺ region 125.

Single crystal substrate 80 and buffer layer 121 are of n conductivity type. The concentration of the n type conduction impurities in buffer layer 121 is 5×10¹⁷ cm⁻³, for example. The thickness of buffer layer 121 is 0.5 μm, for example.

Breakdown voltage holding layer 122 is formed on buffer layer 121, made of n conductivity type silicon carbide. For example, the thickness of breakdown voltage holding layer 122 is 10 μm, and the concentration of the n type conduction impurities is 5×10¹⁵ cm⁻³.

At the surface of breakdown voltage holding layer 122, a plurality of p regions 123 having p type conductivity are formed spaced apart from each other. In and at the surface layer of p region 123, an n⁺ region 124 is formed. A p⁺ region 125 is formed adjacent to n⁺ region 124. Gate insulating film 126 is formed on a region of breakdown voltage holding layer 122 exposed between p regions 123. Specifically, gate insulating film 126 is formed extending from above n⁺ region 124 at one of p regions 123, over p region 123, a region of breakdown voltage holding layer 122 exposed between two p regions 123, the other p region 123, as far as above n⁺ region 124 at the relevant other p region 123. Gate electrode 110 is formed on gate insulating film 126. Source electrode 111 is formed on n⁺ region 124 and p⁺ region 125. Upper source electrode 127 is formed on source electrode 111.

The maximum value of the nitrogen atom concentration at a region within 10 nm from the boundary between gate insulating film 126 and the semiconductor layer including n⁺ region 124, p⁺ region 125, p region 123 and breakdown voltage holding layer 122 is greater than or equal to 1×10²¹ cm⁻³. Accordingly, the mobility at the channel region particularly under gate insulating film 126 (the region in contact with gate insulating film 126 and the portion of p region 123 located between n⁺ region 124 and breakdown voltage holding layer 122).

A method of manufacturing MOSFET 100 will be described hereinafter.

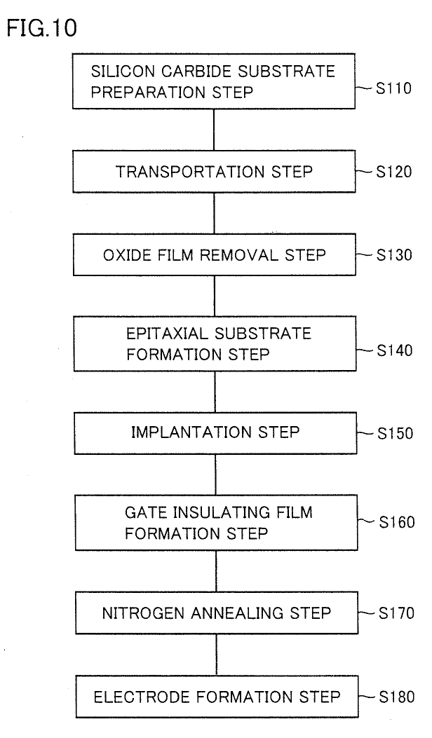

First, silicon carbide substrate 89 described in the first embodiment is prepared (FIG. 10: step S110). Then, silicon carbide substrate 89 is transported from the site where silicon carbide substrate 89 was manufactured to the site where MOSFET 100 is to be manufactured using silicon carbide substrate 89 (FIG. 10: step S120). Then, oxide film 70 is removed (FIG. 10: step S130), as described in the first embodiment.

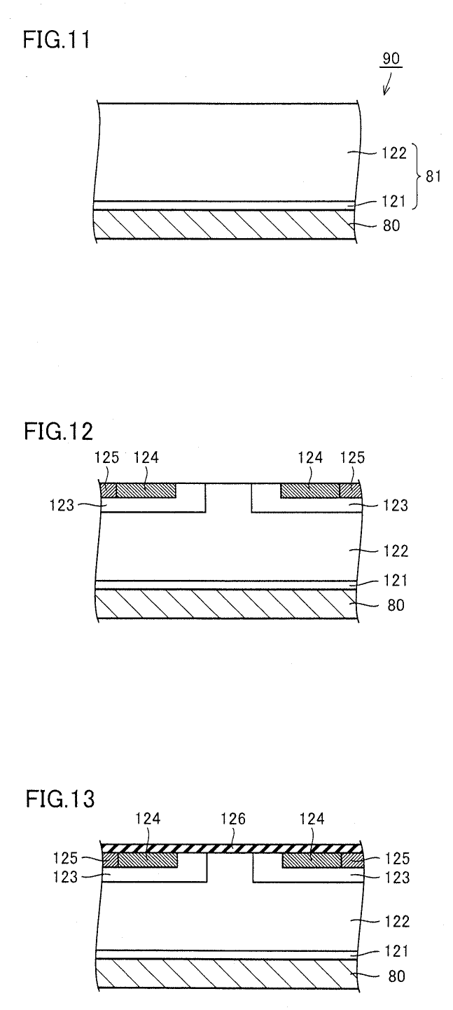

Then, as shown in FIG. 11, epitaxial layer 81 is formed on single crystal substrate 80. Specifically, buffer layer 121 is formed on single crystal substrate 80, and breakdown voltage holding layer 122 is formed on buffer layer 121. Thus, epitaxial substrate 90 is formed (FIG. 10: step S140).

Buffer layer 121 is made of n conductivity type silicon carbide, having a thickness of 0.5 μm, for example. The concentration of the conduction impurities in buffer layer 121 is 5×10¹⁷ cm⁻³, for example. The thickness of breakdown voltage holding layer 122 is set at 10 μm, for example. The concentration of n type conduction impurities at breakdown voltage holding layer 122 is 5×10¹⁵ cm⁻³, for example.

As shown in FIG. 12, by an implantation step (FIG. 10: step S150), p region 123, n⁺ region 124 and p⁺ region 125 are formed as set forth below.

First, p type conduction impurities are selectively introduced into a region of breakdown voltage holding layer 122 to form p region 123. Then, n type conduction impurities are selectively introduced into a predetermined region to form n⁺ region 124. Also, p type conduction impurities are selectively introduced into a predetermined region to form p⁺ region 125. Selective introduction of impurities is carried out using a mask made of an oxide film, for example.

Following such an implantation step, activation annealing is carried out. For example, annealing is carried out for 30 minutes at the heating temperature of 1700° C. in an argon atmosphere, for example.

As shown in FIG. 13, a gate insulating film formation step (FIG. 10: step S160) is carried out. Specifically, gate insulating film 126 is formed to cover breakdown voltage holding layer 122, p region 123, and n⁺ region 124 and p⁺ region 125. This formation may be carried out by dry oxidation (thermal oxidation). The dry oxidization conditions include, for example, a heating temperature of 1200° C. and a heating time of 30 minutes.

Then, a nitride annealing step (FIG. 10: step S170) is carried out. Specifically, annealing is carried out in a nitrogen oxide (NO) atmosphere. The processing conditions include, for example, a heating temperature of 1100° C. and a heating time of 120 minutes. As a result, nitrogen atoms are introduced in the proximity of the boundary between gate insulating film 126 and each of breakdown voltage holding layer 122, p region 123, n⁺ region 124 and p⁺ region 125.

Following this annealing step using nitrogen oxide, an annealing process using argon (Ar) gas that is inert gas may be carried out. The processing conditions include, for example, a heating temperature of 1100° C. and a heating time of 60 minutes.

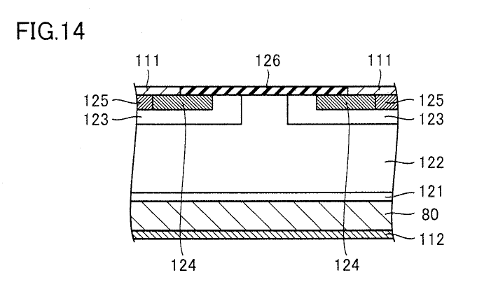

As shown in FIG. 14, by an electrode formation step (FIG. 10: step S180), source electrode 111 and drain electrode 112 are formed as set forth below.

On gate insulating film 126, a resist film having a pattern is formed by photolithography. Using this resist film as a mask, the region of gate insulating film 126 located above n⁺ region 124 and p⁺ region 125 is removed by etching. Accordingly, an opening is formed at gate insulating film 126. At this opening, a conductor film is formed to be brought into contact with each of n⁺ region 124 and p⁺ region 125. Then, by removing the resist film, the region of the aforementioned conductor film located on the resist film is removed (lift off). The conductor film may be a metal film, for example nickel (Ni). As a result of the lift off, source electrode 111 is formed.

At this stage, heat treatment is preferably carried out for alloying. For example, heat treatment is carried out for 2 minutes at the heating temperature of 950° C. in an atmosphere of argon (Ar) gas that is inert gas.

Referring to FIG. 9 again, upper source electrode 127 is formed on source electrode 111. Also, gate electrode 110 is formed on gate insulating film 126. Furthermore, drain electrode 112 is formed on the back face (in the drawing, bottom face) of single crystal substrate 80.

Thus, a MOSFET 100 is obtained.

According to the present embodiment, during the transportation of silicon carbide substrate 89 (FIG. 1), silicon carbide substrate 89 has oxide film 70 formed. Since an effect caused by transportation occurs mainly at oxide film 70, any effect caused by transportation on the property of MOSFET 100 can be suppressed by removing oxide film 70 after transportation.

More specifically, prior to annealing at a temperature greater than or equal to approximately 1000° C. such as activation annealing, a mechanical scratch generated at the time of transportation of silicon carbide substrate 89 (FIG. 10: step S 120) can be eliminated by removing oxide film 70 (FIG. 10: step S130). Accordingly, development of a stacking fault in the silicon carbide single crystal with a mechanical scratch as an origin can be prevented. Since the stacking fault in MOSFET 100 can be reduced, the reliability of MOSFET 100 can be improved.

### Fourth Embodiment

A MOSFET 100 similar to that of the third embodiment (FIG. 9) is manufactured in the present embodiment. A method of manufacturing MOSFET 100 of the fourth embodiment will be described hereinafter.

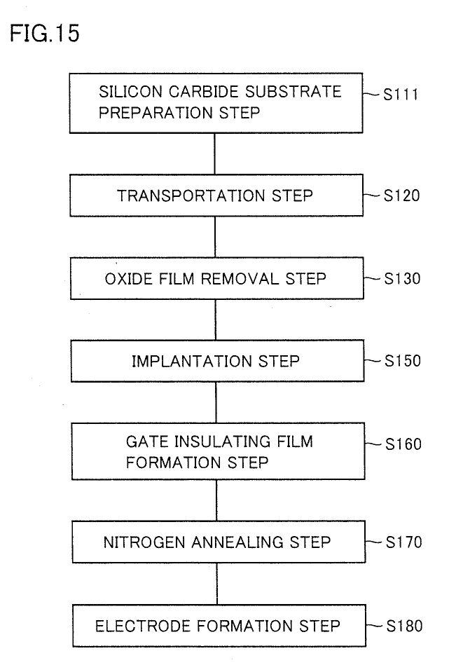

First, silicon carbide substrate 99 (FIG. 7) is prepared (FIG. 15: step S111), as described in the second embodiment. Then, silicon carbide substrate 99 is transported from the site where silicon carbide substrate 99 was manufactured to the site where MOSFET 100 (FIG. 9) is to be manufactured using silicon carbide substrate 99 (FIG. 15: step S120). Then, oxide film 70 is removed (FIG. 15: step S130), as described in the second embodiment.

Then, through steps similar to those shown in FIGS. 12-14 of the first embodiment (FIG. 15: steps S150-S180), a MOSFET (FIG. 9) is obtained. Advantages similar to those of the third embodiment are achieved in the present embodiment.

In the third and fourth embodiments, a configuration in which the conductivity types are interchanged, i.e. the p type and n type exchanged, can be employed. Furthermore, although the description is based on MOSFET 100, the semiconductor device may be a metal insulator semiconductor FET (MISFET) other than a MOSFET. Moreover, the semiconductor device is not limited to a MISFET, and may be an IGBT (Insulated Gate Bipolar Transistor) or a JFET (Junction FET).

### EXAMPLES

### Example 1

The nitrogen dioxide concentration of the atmosphere in container 30 (FIG. 5) was intentionally increased. Single crystal substrate 80 was stored for 2 hours under this atmosphere. The oxygen concentration was set at the constant level of 20% by volume.

As a result, oxide film 70 (FIG. 6) was formed on single crystal substrate 80. When the value of the nitrogen dioxide concentration was 2 μg/m³, 5 μg/m³ and 10 μg/m³, the thickness of oxide film 70 was 1.3 nm, 1.4 nm and 1.6 nm, respectively. In other words, the thickness of oxide film 70 was greater than or equal to 1 nm.

### Comparative Example 1

In contrast to Example 1, the nitrogen dioxide concentration in the atmosphere was not intentionally increased. As a result, the nitrogen dioxide concentration was 0.3 μg/m³, and the thickness of oxide film 70 (FIG. 6) was 0.7 nm. In other words, the thickness of oxide film 70 was less than 1 nm.

By applying SPM cleaning to single crystal substrate 80 with oxide film 70 obtained in Example 1 and Comparative Example 1, oxide film 70 was removed. Then, each single crystal substrate 80 was heated for 2 hours at 1000° C. The development of a stacking fault from the surface of single crystal substrate 80 caused by the heating was observed. As compared to the development of a stacking fault at single crystal substrate 80 of Comparative Example 1, the development of a stacking fault at single crystal substrate 80 of Example 1 was suppressed to 67%, 65% and 60%, when the nitrogen dioxide concentration was 2 μg/m³, 5 μg/m³ and 10 μg/m³, respectively.

### Example 2

The oxygen concentration of the atmosphere in container 30 (FIG. 5) was adjusted intentionally. Single crystal substrate 80 was stored for 2 hours under this atmosphere. The nitrogen dioxide concentration was set at the constant level of 2 μg/m³.

As a result, oxide film 70 (FIG. 6) was formed on single crystal substrate 80. When the value of the oxygen concentration was 18% by volume, 20% by volume and 22% by volume, the thickness of oxide film 70 was 1.1 nm, 1.3 nm and 1.3 nm, respectively. In other words, the thickness of oxide film 70 was greater than or equal to 1 nm.

### Comparative Example 2

The nitrogen dioxide concentration and the oxygen concentration of the atmosphere in container 30 (FIG. 5) were set at 2 μg/m³ and 16% by volume, respectively. Single crystal substrate 80 was stored for 2 hours under this atmosphere. As a result, oxide film 70 (FIG. 6) formed on single crystal substrate 80 had the thickness of 0.8 nm. In other words, the thickness of oxide film 70 was less than 1 nm.

### Example 3

The vapor concentration of the atmosphere in container 30 (FIG. 5) was adjusted intentionally. Single crystal substrate 80 was stored for 2 hours under this atmosphere. The nitrogen dioxide concentration was set at the constant level of 2 μg/m³.

As a result, oxide film 70 (FIG. 6) was formed on single crystal substrate 80. When the value of the vapor concentration was 25 g/m³ and 30 g/m³, the thickness of oxide film 70 was 1.2 nm and 1.3 nm, respectively. In other words, the thickness of oxide film 70 was greater than or equal to 1 nm.

### Comparative Example 3

The nitrogen dioxide concentration, the oxygen concentration, and the vapor concentration of the atmosphere in container 30 (FIG. 5) were set at 2 μg/m³, 16% by volume, and 20 g/m³, respectively. Single crystal substrate 80 was stored for 2 hours under this atmosphere. As a result, the thickness of oxide film 70 (FIG. 6) formed on single crystal substrate 80 was 0.9 nm. In other words, the thickness of oxide film 70 was less than 1 nm.

### Example 4

The nitrogen dioxide concentration and the oxygen concentration of the atmosphere in container 30 (FIG. 5) were set at 2 μg/m³ and 20% by volume, respectively. The thickness over time of oxide film 70 formed on single crystal substrate 80 under this atmosphere was evaluated. At the point in time corresponding to an elapse of 30 minutes, 60 minutes, 90 minutes, 120 minutes, 150 minutes and 180 minutes, the thickness of oxide film 70 was 0.4 nm, 0.8 nm, 1.1 nm, 1.3 nm, 1.3 nm and 1.3 nm, respectively. When the nitrogen dioxide concentration was modified to 5 μg/m³, the thickness of oxide film 70 was 0.4 nm, 0.9 nm, 1.2 nm, 1.4 nm, 1.4 nm, and 1.4 nm at the point in time corresponding to an elapse of 30 minutes, 60 minutes, 90 minutes, 120 minutes, 150 minutes and 180 minutes, respectively. When the nitrogen dioxide concentration was modified to 10 μg/m³, the thickness of oxide film 70 was 0.8 nm, 1.2 nm, 1.5 nm, 1.6 nm, 1.7 nm and 1.7 nm at the point in time corresponding to an elapse of 30 minutes, 60 minutes, 90 minutes, 120 minutes, 150 minutes and 180 minutes, respectively.

From the foregoing, it was appreciated that the thickness of oxide film 70 was substantially saturated at the elapse of 2 hours.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A method of manufacturing a silicon carbide substrate, comprising the steps of:
preparing a silicon carbide substrate, and
forming an oxide film on said silicon carbide substrate by exposing said silicon carbide substrate to an atmosphere having a nitrogen dioxide concentration greater than or equal to 2 μg/m³.

2. The method of manufacturing a silicon carbide substrate according to claim 1, wherein said atmosphere has a nitrogen dioxide concentration greater than or equal to 5 μg/m³.

3. The method of manufacturing a silicon carbide substrate according to claim 2, wherein said atmosphere has a nitrogen dioxide concentration greater than or equal to 10 μg/m³.

4. The method of manufacturing a silicon carbide substrate according to claim 1, wherein said atmosphere has an oxygen concentration greater than or equal to 18% by volume.

5. The method of manufacturing a silicon carbide substrate according to claim 1, wherein said atmosphere has a vapor concentration greater than or equal to 25 g/m³.

6. The method of manufacturing a silicon carbide substrate according to claim 1, wherein said step of forming an oxide film includes the step of exposing said silicon carbide substrate to said atmosphere for two or more hours.

7. The method of manufacturing a silicon carbide substrate according to claim 1, wherein said atmosphere has a nitrogen dioxide concentration less than or equal to 2 mg/m³.

8. A method of manufacturing a silicon carbide semiconductor device comprising the steps of:
preparing a silicon carbide substrate,
forming an oxide film on said silicon carbide substrate by exposing said silicon carbide substrate to an atmosphere having a nitrogen dioxide concentration greater than or equal to 2 μg/m³,
transporting said silicon carbide substrate with said oxide film formed, and
subsequent to said step of transporting said silicon carbide substrate, removing said oxide film.
